(19) United States
(12) Patent Application Publication
(10) Pub. No.: US 2026/0215323 A1
(43) Pub. Date: Jul. 23, 2026

(54) SEMICONDUCTOR PACKAGE

(71) Applicant: MEDIATEK INC., Hsinchu City (TW)

(72) Inventors: Bo-Jiun LIN, Hsinchu City (TW); Po-Lin SU, Hsinchu City (TW); Kuo-Lung FAN, Hsinchu City (TW); Pei-Haw TSAO, Hsinchu City (TW)

(21) Appl. No.: 19/447,156

(22) Filed: Jan. 13, 2026

Related U.S. Application Data
(60) Provisional application No. 63/746,303, filed on Jan. 17, 2025.

(51) Int. Cl. H10W 72/90; H10W 70/40; H10W 74/10

(52) U.S. Cl. CPC H10W 72/9415; H10W 70/411; H10W 74/111

(57) ABSTRACT

A semiconductor package is provided. The semiconductor package includes an exposed pad, at least one extension portion, a die, and a molding compound. The extension portion is connected to the exposed pad and extends on a plane of a bottom surface of the exposed pad. The die is mounted on a top surface of the exposed pad. The top surface is opposite the bottom surface. The molding compound encapsulates the die and surrounds the exposed pad and the extension portion. The bottom surface of the exposed pad and a bottom surface of the extension portion are exposed from the molding compound.

### CROSS REFERENCE TO RELATED APPLICATIONS

This application claims the benefit of U.S. provisional application No. 63/746,303, filed on Jan. 17, 2025, the entirety of which is incorporated by reference herein.

### TECHNICAL FIELD

The present disclosure relates to a semiconductor package, and, in particular, it relates to a leadframe-based semiconductor package.

### BACKGROUND

Quad flat no-lead (QFN) packages are known for their small size, cost-effectiveness, and good production yields. QFN packages also possess certain mechanical advantages for high-speed circuits, including improved co-planarity and heat dissipation.

The technological trends currently guiding the back-end packaging industry can be summarized by the phrase, “more functionality in a smaller space”. The space of these integrated circuit chips is becoming smaller, leading to a thinning down of the thickness of the leadframe package. As the thickness of the leadframe package is thinned down, strain may occur at or near the interface between different materials, causing the leadframe package to suffer from die cracking.

Therefore, there is a strong need in this industry to provide an improved leadframe structure and leadframe package to avoid the cracking problem.

### BRIEF SUMMARY

An embodiment of the present disclosure provides a semiconductor package. The semiconductor package includes an exposed pad, at least one extension portion, a die, and a molding compound. The at least one extension portion is connected to the exposed pad and extends on a plane of a bottom surface of the exposed pad. The die is mounted on a top surface of the exposed pad. The top surface is opposite the bottom surface. The molding compound encapsulates the die and surrounds the exposed pad and the at least one extension portion. The bottom surface of the exposed pad and a bottom surface of the at least one extension portion are exposed from the molding compound.

An embodiment of the present disclosure provides a semiconductor package. The semiconductor package includes a leadframe, a die, and a molding compound. The leadframe includes an exposed pad, a tie bar, leads and a first extension portion. The tie bar extends from a corner of the exposed pad. The leads are arranged around and spaced apart from the exposed pad. The first extension portion is connected to the exposed pad. The first extension portion overlaps at least one of the leads or the tie bar. The die is mounted on a top surface of the exposed pad. The molding compound encapsulates the die and covering the leadframe. A bottom surface of the exposed pad and a bottom surface of the first extension portion are exposed from the molding compound.

### BRIEF DESCRIPTION OF THE DRAWINGS

The present disclosure can be more fully understood by reading the subsequent detailed description and examples with references made to the accompanying drawings, wherein:

FIG. 1 is a schematic bottom view of a semiconductor package in accordance with some embodiments of the disclosure;

FIG. 2A is a schematic cross-sectional view along the line A-A′ of the semiconductor package in accordance with some embodiments of the disclosure shown in FIG. 1;

FIG. 2B is a schematic cross-sectional view along the line B-B′ of the semiconductor package in accordance with some embodiments of the disclosure shown in FIG. 1;

FIG. 2C is a schematic cross-sectional view along the line C-C′ of the semiconductor package in accordance with some embodiments of the disclosure shown in FIG. 1;

FIG. 3A is a schematic cross-sectional view along the line A-A′ of the semiconductor package in accordance with some embodiments of the disclosure shown in FIG. 1;

FIG. 3B is a schematic cross-sectional view along the line B-B′ of the semiconductor package in accordance with some embodiments of the disclosure shown in FIG. 1;

FIG. 3C is a schematic cross-sectional view along the line C-C′ of the semiconductor package in accordance with some embodiments of the disclosure shown in FIG. 1;

FIG. 4 is a schematic bottom view of a semiconductor package in accordance with some embodiments of the disclosure;

FIG. 5A is a schematic cross-sectional view along the line A-A′ of the semiconductor package in accordance with some embodiments of the disclosure shown in FIG. 4;

FIG. 5B is a schematic cross-sectional view along the line B-B′ of the semiconductor package in accordance with some embodiments of the disclosure shown in FIG. 4;

FIG. 6 is a schematic bottom view of a semiconductor package in accordance with some embodiments of the disclosure;

FIG. 7 is a schematic bottom view of a semiconductor package in accordance with some embodiments of the disclosure;

FIG. 8 is a schematic bottom view of a semiconductor package in accordance with some embodiments of the disclosure; and

FIG. 9 is a schematic bottom view of a semiconductor package in accordance with some embodiments of the disclosure.

### DETAILED DESCRIPTION

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

There are various leadframe-based surface mount products, such as quad flat no-lead (QFN) package, advanced QFN (aQFN) package, low-profile quad flat package (LQFP) or the like. A package can be attached to a printed circuit board (PCB) by, for example, soldering it to the PCB. The attachment of the packages (i.e. packaged integrated circuit) to PCBs produces printed circuit board assemblies (PCBAs), which can be used as motherboards in computers, portable devices such as mobile phone, tablets, notebooks, etc.

Generally, a leadframe strip is populated with a plurality of leadframes. A semiconductor die or microelectronic device may be mounted on each leadframe and encapsulated with a molding compound (e.g., epoxy molding compound (EMC)). Leadframes are separated during singulation of the strip to create individual semiconductor packages. One type of the semiconductor packages is a flat-pack no-lead package where each terminal is exposed at the bottom and at a side of the package. Typically, the sawing process during singulation of the strip typically results in lead terminals that have at least some exposed base metal on a cut end, or flank, of each lead terminal. Typically, the aforesaid cut end is vertically flush with a sidewall surface of the package or the sidewall surface of a molding compound.

The term of quad flat no-lead or small outline no-lead package indicates that the leads do not have cantilevered leads, but flat leads, which are typically arrayed along the periphery of the packaged device. The metal of the leads may be connected by solder material to the metal of respective contact pads of an external part. QFN packages typically use a copper leadframe for the die assembly and PCB interconnection.

When the leadframe-based package is continuously sized down, the thinner package bodies are more prone to bending and have a higher risk of cracking. The adhesion between materials (such as copper and the molding compound) is less than the stress induced by package deformation. Cracks can rapidly propagate through the material interface, especially when the stress is perpendicular to the interface. The thinner the package, the greater the risk of cracking. When the packages are arranged in a row, cracks can quickly spread along the material interfaces of each package, causing all the packages in the row to crack or break.

Embodiments provide a quad flat no-lead (QFN) type package. However, those of ordinary skill in the art will readily understand the details of the invention and that the invention is applicable to other lead frame-based package types.

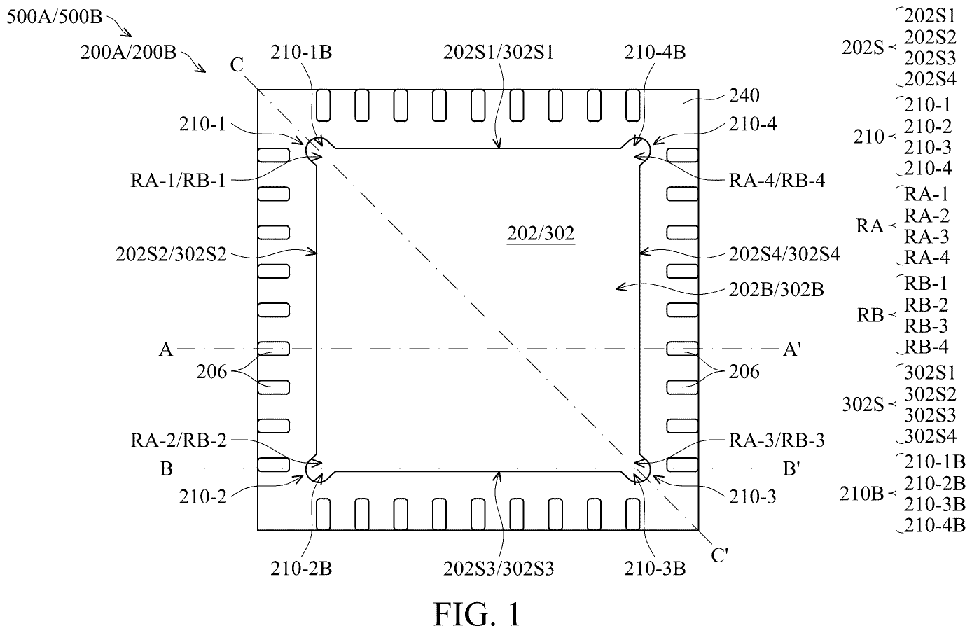

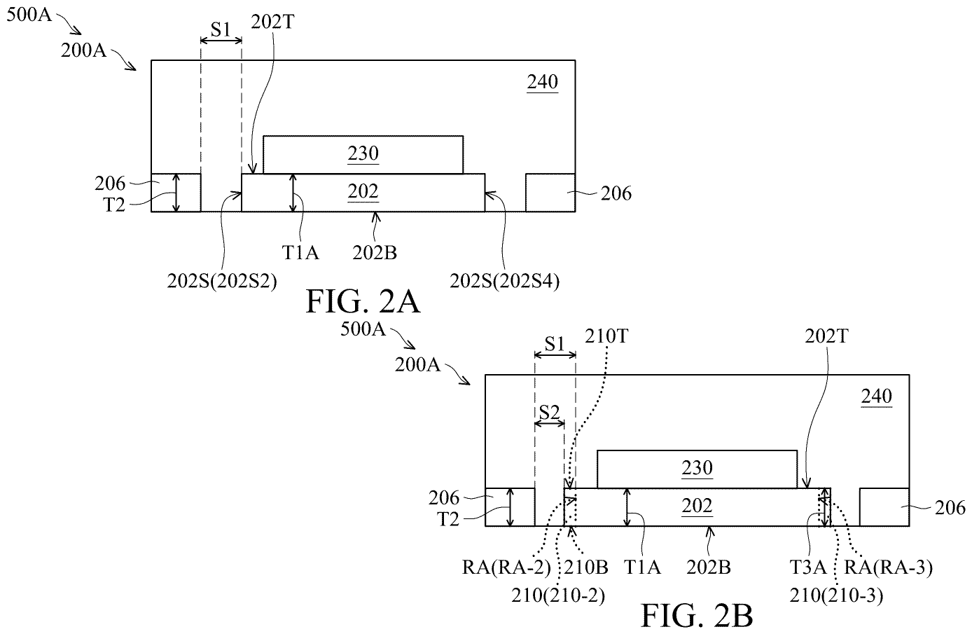

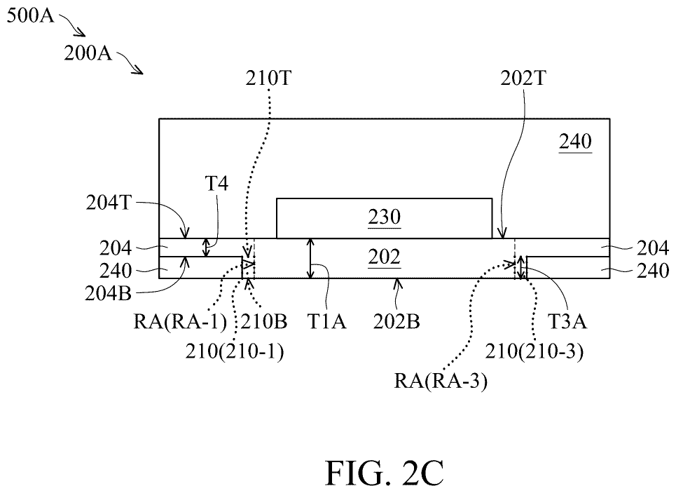

FIG. 1 is a schematic bottom view of a semiconductor package 500A in accordance with some embodiments of the disclosure. FIG. 2A is a schematic cross-sectional view along the line A-A′ of the semiconductor package 500A in accordance with some embodiments of the disclosure shown in FIG. 1. FIG. 2B is a schematic cross-sectional view along the line B-B′ of the semiconductor package 500A in accordance with some embodiments of the disclosure shown in FIG. 1. FIG. 2C is a schematic cross-sectional view along the line C-C′ of the semiconductor package 500A in accordance with some embodiments of the disclosure shown in FIG. 1. In some embodiments, the semiconductor package 500A, for example, a quad flat no-lead (QFN) type package, includes a leadframe 200A, a die 230, and a molding compound 240. The leadframe 200A includes an exposed pad 202, tie bars 204, leads 206, and at least one extension portion 210.

The exposed pad (also called a die paddle) 202 is located at a central region of the semiconductor package 500A. In addition, the exposed pad 202 is supported by four tie bars 204 extending from four corners (e.g., extension corners RA-1, RA-2, RA-3, and RA-4) of the exposed pad 202 to corresponding four corner regions of the semiconductor package 500A. More specifically, one end of each of the four tie bars 204 terminates at the exposed pad 202 and the other end of each of the four tie bars 104 terminates at the edge of the leadframe 200A.

The exposed pad 202 having a top surface 202T and a bottom surface 202B, the top surface 202T is opposite the bottom surface 202B. For example, the top surface 202T of the exposed pad 202 is provided for the die 230 mounted on it. The bottom surface 202B of exposed pad 202 of the semiconductor package 500A may be exposed for better heat dissipation. In some embodiments, in a plane view (e.g., the bottom view), the exposed pad 202 has a rectangular shape, a rounded rectangular shape or circular shape. For example, the exposed pad 202 has a rectangular shape.

The leads 206 are arranged along and extends outwardly side surfaces 202S of the exposed pad 202. In addition, the leads 206 are arranged spaced apart from the exposed pad 202. In some embodiments, the leads 206 are arranged by a predetermined spacing and pitch according to design requirements. In addition, the leads 206 may be arranged in single row or multi rows depending upon various design requirements.

In cross-sectional view along the side surface 202S of the exposed pad 202 (FIG. 2B), the thickness T1A of the exposed pad 202 can be the same as the thickness T2 of the leads 206. In some embodiments, the thickness T1A of the exposed pad 202 can also be different from the thickness T2 of the leads 206.

It should be noted that the number of leads 206 and dimension of the semiconductor package 500A are only an example and is not a limitation to the present disclosure. In some embodiments, a power ring and/or a ground ring (not shown) may be optionally disposed between the leads 206 and the exposed pad 202.

The extension portions 210 (including extension portions 210-1, 210-2, 210-3, and 210-4) is connected to the exposed pad 202. In addition, the extension portions 210 may extend on a plane of the bottom surface 202B of the exposed pad 202, as shown in FIG. 2B. In some embodiments, the bottom surface 202B of the exposed pad 202 is flush with the bottom surfaces 210-1B, 210-2B, 210-3B, and 210-4B of the extension portions 210-1, 210-2, 210-3, and 210-4.

In some embodiments, when the exposed pad 202 is rectangular or rounded rectangular, the extension portions 210 are connected to corresponding corners RA (including extension corners RA-1, RA-2, RA-3, and RA-4) of the exposed pad 202. For example, the extension portions 210-1, 210-2, 210-3, and 210-4 are connected to the corresponding corners RA-1, RA-2, RA-3, and RA-4) of the exposed pad 202, respectively. In some embodiments, when the exposed pad 202 is rectangular, rounded rectangular or circular, the extension portions 210 overlaps the corresponding tie bars 204.

In some embodiments, the extension portions 210 may extend outwardly the corresponding corners RA. The extension portions 210 may extend beyond the side surfaces 202S of the exposed pad 202 adjacent to the corresponding corners RA. In addition, when the exposed pad 202 is rectangular or rounded rectangular, the extension portions 210 may extend outwardly substantially along the diagonals of the exposed pad 202. Furthermore, when the exposed pad 202 circular, the extension portions 210 may extend outwardly substantially along the diameter of the exposed pad 202. In some embodiments as shown in FIG. 2B, the extension portions 210 may located between the exposed pad 202 and the leads 206.

In some embodiments in which the extension portions 210 extend outwardly the corresponding corners RA of the exposed pad 202 (and close to the leads 206), the spacing S1 between the leads 206 and the exposed pad 202 is greater than the spacing S2 between the leads 206 and the extension portion 210. In addition, the spacing between the corner RA of the exposed pad 202 (i.e., the spacing S1) is greater than the spacing S2 between the leads 206 and the extension portion 210.

In the cross-sectional view along the side surface 202S of the exposed pad 202 (FIG. 2B), the thickness T1A of the exposed pad 202 is the same as the thickness T3A of the extension portion 210. The top surface 202T of the exposed pad 202 is flush with the top surface 210T of the extension portion 210.

In the cross-sectional view along the diagonal of the exposed pad 202 (FIG. 2C), the top surface 202T of the exposed pad 202 is flush with the top surface 204T of the tie bar 204. The top surface 210T of the extension portion 210 may be located below the top surface 204T of the tie bar 204.

In some embodiments, the extension portion 210 is directly below and overlaps the tie bar 204. The top surface 210T of the extension portion 210 may be in contact with the bottom surface 204B of the tie bar 204. The thickness T1A of the exposed pad 202 is the sum of the thickness T3A of the extension portion 210 and the thickness T4 of the tie bar 204.

In some embodiments, each of the extension portions 210 has a smooth outer contour. For example, each of the extension portions 210 has a rounded edge.

The die 230 is mounted on the top surface 202T of the exposed pad 202 through a conductive adhesive layer (not shown) including conductive particles (also called fillers) dispersing in a polymer matrix.

In some embodiments, the die 230 includes a plurality of conductive pads (not shown), for example, input/output (I/O) pads, disposed along a boundary of an active surface 230T of the die 230. In some embodiments, the conductive pads of the die 230 are coupled (electrically connected) to the corresponding leads 206 through conductive wires (not shown). Therefore, the leads 206 may transmit signals (or power) from or to the die 230. In some embodiments, the conductive wires, for example, a bond wire, includes a copper wire or a gold wire, or other applicable conductive wires.

The molding compound 240 may encapsulate the die 230 and covers the leadframe 200A. In addition, the molding compound 240 may partially encapsulate inner ends of the leads 220 and tie bars 204 and leave outer ends of the leads 220 and tie bars 204 exposed from the molding compound 240. In some embodiments, the molding compound 240 may encapsulate both the inner end (close to the exposed pad 202) and the outer end (away from the exposed pad 202) of the extension portion 210.

In some embodiments, the bottom surface 202B of the exposed pad 202 and the 210-1B, 210-2B, 210-3B, and 210-4B of the extension portions 210-1, 210-2, 210-3, and 210-4 may be exposed from the molding compound 240. In addition, the bottom surface 202B of the exposed pad 202 and the bottom surface 210B of the extension portion 210 may be connected to a ground plane and/or heat-dissipating plugs (not shown) in a base (not shown) such as a printed circuit board (PCB). In some embodiments, the molding compound 240 may comprise silicon particle-filled polymer material applied under heat and pressure by transfer molding.

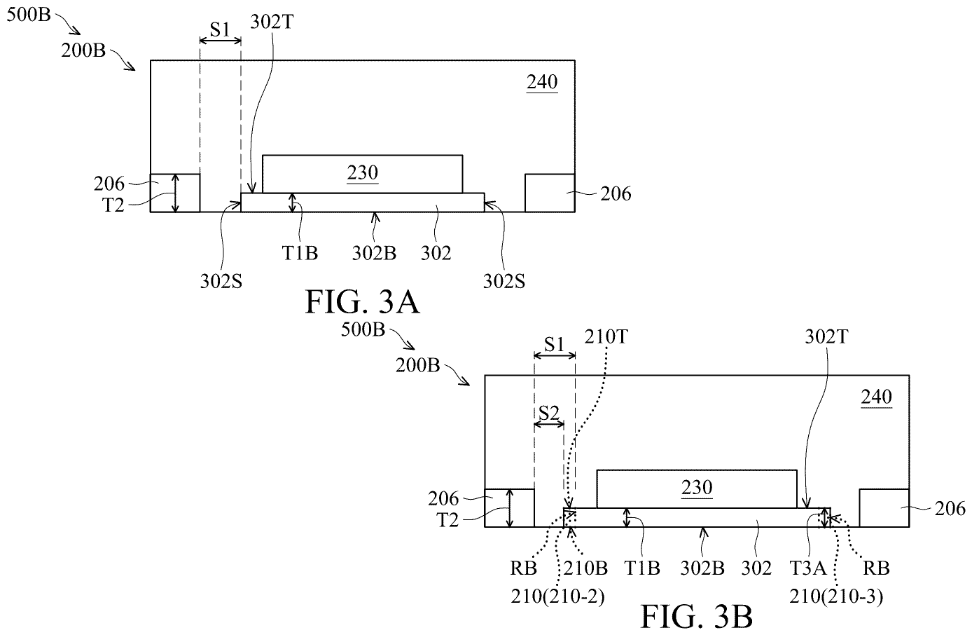

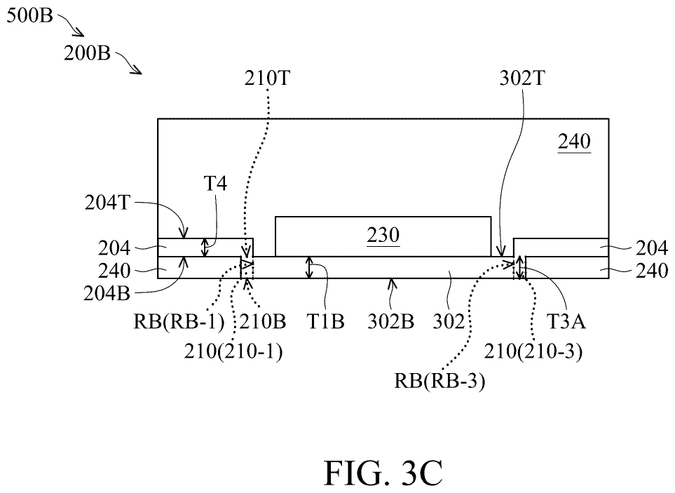

FIG. 1 is also a schematic bottom view of a semiconductor package 500B in accordance with some embodiments of the disclosure. FIG. 3A is a schematic cross-sectional view along the line A-A′ of the semiconductor package 500B in accordance with some embodiments of the disclosure shown in FIG. 1. FIG. 3B is a schematic cross-sectional view along the line B-B′ of the semiconductor package 500B in accordance with some embodiments of the disclosure shown in FIG. 1. FIG. 3C is a schematic cross-sectional view along the line C-C′ of the semiconductor package 500B in accordance with some embodiments of the disclosure shown in FIG. 1. Elements of the embodiments that are the same or similar to those previously described with reference to FIGS. 1 and 2A-2C are not repeated herein, in the interests of brevity.

As shown in FIGS. 1, 2A-2C and 3A-3C, the difference between the semiconductor package 500A and the semiconductor package 500B at least includes that the semiconductor package 500B may include a leadframe 200B having a thinned exposed pad 302 in order to reduce the total height of the semiconductor package. For example, the thickness T1B of the exposed pad 302 of the semiconductor package 500B is thinner than the thickness T1A of the exposed pad 202 of the semiconductor package 500A.

In cross-sectional view along the extending direction of the leads 206 (FIG. 3A), the thickness T1B of the exposed pad 302 is thinner than the thickness T2 of the leads 206.

In the cross-sectional view along the side surface 302S of the exposed pad 302 (FIG. 3B), the thickness T1B of the exposed pad 302 may be the same as the thickness T3A of the extension portion 210. The top surface 302T of the exposed pad 302 may be flush with the top surface 210T of the extension portion 210.

In the cross-sectional view along the diagonal of the exposed pad 302 (FIG. 3C), the thickness T1B of the exposed pad 302 is the same as the thickness T3A of the extension portion 210. The top surface 302T of the exposed pad 302 and the top surface 210T of the extension portion 210 may be located below the top surface 204T of the tie bar 204. The exposed pad 302 may be separated from the tie bar 204 through the extension portion 210.

In some embodiments, the extension portion 210 is directly below and overlaps the tie bar 204. The top surface 210T of the extension portion 210 may be in contact with the bottom surface 204B of the tie bar 204.

In addition, the thickness T1B of the exposed pad 302 may be thinner than the sum of the thickness T3A of the extension portion 210 and the thickness T4 of the tie bar 204.

As shown in FIGS. 3A-3C, the die 230 is mounted on the top surface 302T of the exposed pad 302. The molding compound 240 may encapsulate the die 230 and covers the leadframe 200B. In some embodiments, the bottom surface 302B of the exposed pad 302 and the bottom surface 210B of the extension portion 210 may be exposed from the molding compound 240.

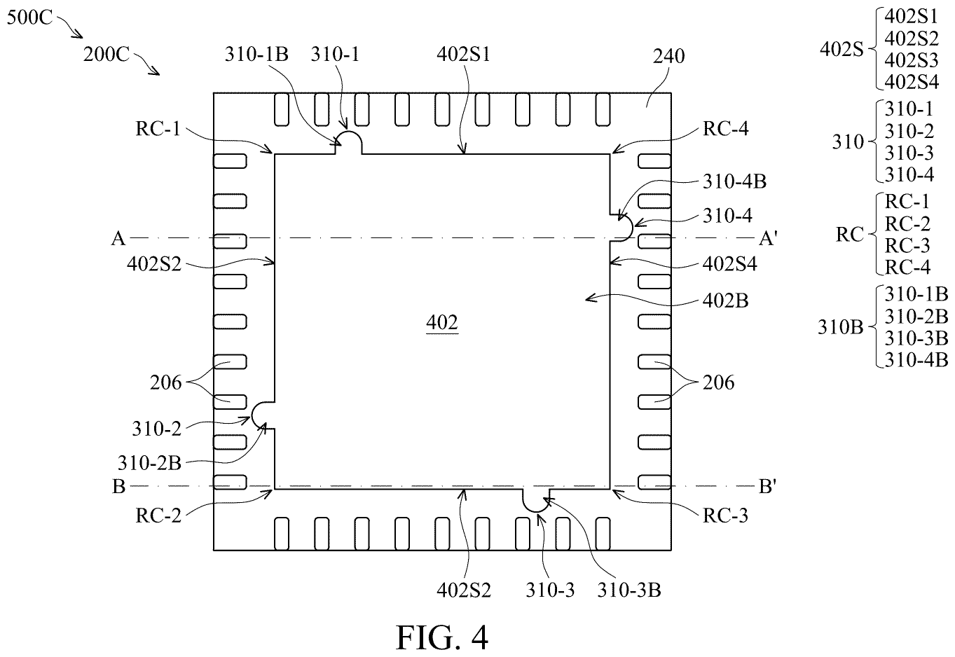

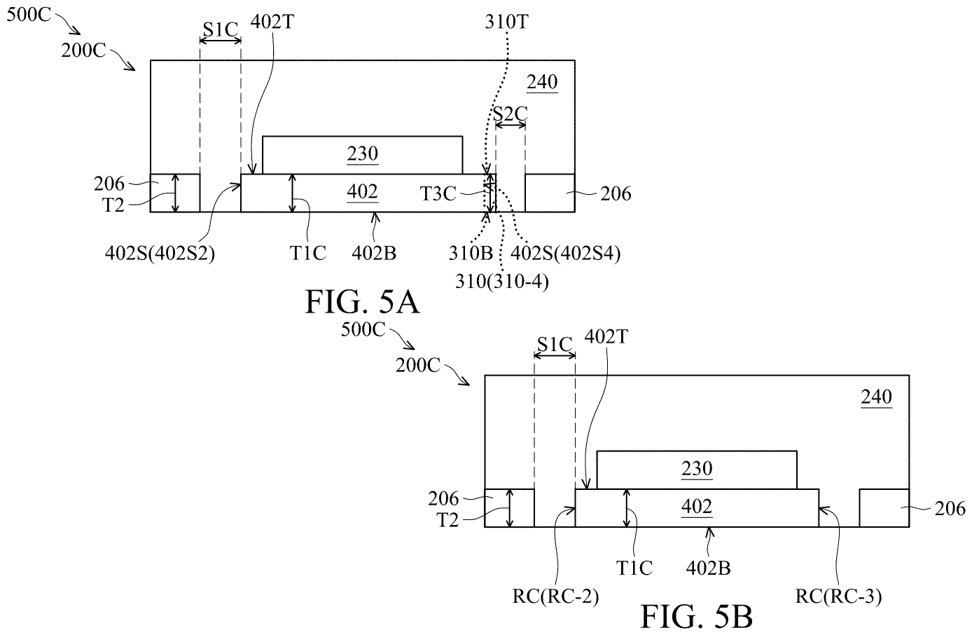

FIG. 4 is a schematic bottom view of a semiconductor package 500C in accordance with some embodiments of the disclosure. FIG. 5A is a schematic cross-sectional view along the line A-A′ of the semiconductor package 500C in accordance with some embodiments of the disclosure shown in FIG. 4. FIG. 5B is a schematic cross-sectional view along the line B-B′ of the semiconductor package 500C in accordance with some embodiments of the disclosure shown in FIG. 4. Elements of the embodiments that are the same or similar to those previously described with reference to FIG. 1, 2A-2C, and are not repeated herein, in the interests of brevity.

As shown in FIG. 1, FIGS. 2A-2C (or FIGS. 3A-3C), FIG. 4 and FIGS. 5A-5B, the difference between the semiconductor package 500A (or the semiconductor package 500B) and the semiconductor package 500C at least includes that the semiconductor package 500C includes a leadframe 200C having extension portions 310 (including extension portions 310-1, 310-2, 310-3, 310-4) connected to side surfaces 402S of an exposed pad 402.

As shown in FIG. 4, the exposed pad 402 having a rectangular shape may include four side surface 402S1, 402S2, 402S3, and 402S4 and four corners RC-1, RC-2, RC-3, and RC-4. In some embodiments, the corners RC-1, RC-2, RC-3, and RC-4 are sharp corners.

In some embodiments, the four extension portions 310-1, 310-2, 310-3, 310-4 are connected to the four side surfaces 402S1, 402S2, 402S3, and 402S4 of the exposed pad 402, respectively. For example, the extension portion 310-1 is connected to the side surface 402S1 adjacent to the side surfaces 402S2, 402S4 and close to the corner RC-1 between the side surface 402S1 and 402S2. The extension portion 310-2 is connected to the side surface 402S2 adjacent to the side surfaces 402S1, 402S3 and close to the corner RC-2 between the side surface 402S2 and 402S3. The extension portion 310-3 is connected to the side surface 402S3 adjacent to the side surfaces 402S2, 402S4 and close to the corner RC-3 between the side surface 402S3 and 402S4. The extension portion 310-4 is connected to the side surface 402S4 adjacent to the side surfaces 402S3, 402S1 and close to the corner RC-4 between the side surface 402S4 and 402S1.

Alternatively, the extension portion 310-1 is connected to the side surface 402S1 adjacent to the side surfaces 402S2, 402S4 and close to the corner RC-4 between the side surface 402S1 and 402S4. The extension portion 310-2 is connected to the side surface 402S2 adjacent to the side surfaces 402S1, 402S3 and close to the corner RC-1 between the side surface 402S1 and 402S2. The extension portion 310-3 is connected to the side surface 402S3 adjacent to the side surfaces 402S2, 402S4 and close to the corner RC-2 between the side surface 402S2 and 402S3. The extension portion 310-4 is connected to the side surface 402S4 adjacent to the side surfaces 402S3, 402S1 and close to the corner RC-3 between the side surface 402S3 and 402S4.

In some embodiments, since the extension portions 310-1, 310-2, 310-3, and 310-4 are close to different corners RC-1, RC-2, RC-3, and RC-4 of the exposed pad 402, the extension portion 310-1 is arranged far from the extension portions 310-2 and 310-4, the extension portion 310-2 is arranged far from the extension portions 310-1 and 310-3, the extension portion 310-3 is arranged far from the extension portions 310-2 and 310-4, and the extension portion 310-4 is arranged far from the extension portions 310-3 and 310-1.

In some embodiments, the extension portions 310-1, 310-2, 310-3, and 310-4 are not connected to the central portion of the corresponding side surfaces 402S1, 402S2, 402S3, and 402S4 of the exposed pad 402.

In some embodiments, the extension portions 310-1, 310-2, 310-3, and 310-4 may extend outwardly the corresponding side surfaces 402S1, 402S2, 402S3, and 402S4 of the exposed pad 402. For example, the extension portion 310-1 may extend substantially vertical to the side surface 402S1 of the exposed pad 402. The extension portion 310-2 may extend substantially vertical to the side surface 402S2 of the exposed pad 402. The extension portion 310-3 may extend substantially vertical to the side surface 402S3 of the exposed pad 402. The extension portion 310-4 may extend substantially vertical to the side surface 402S4 of the exposed pad 402. Since the side surface 402S1 is substantially vertical to the side surfaces 402S2 and 402S4, the extension portion 310-1 is substantially vertical to the extension portions 310-2 and 310-4. Since the side surface 402S2 is substantially vertical to the side surfaces 402S1 and 402S3, the extension portion 310-2 is substantially vertical to the extension portions 310-1 and 310-3. Since the side surface 402S3 is substantially vertical to the side surfaces 402S2 and 402S4, the extension portion 310-3 is substantially vertical to the extension portions 310-2 and 310-4. Since the side surface 402S4 is substantially vertical to the side surfaces 402S3 and 402S1, the extension portion 310-4 is substantially vertical to the extension portions 310-3 and 310-1.

In some embodiments in which the extension portions 310 extend outwardly the corresponding side surfaces 402S1, 402S2, 402S3, and 402S4 of the exposed pad 402 (and toward to the leads 206), the spacing S1C between the leads 206 and the exposed pad 402 is greater than the spacing S2C between the leads 206 and the extension portion 310 in the cross-sectional view along the extending direction of the extension portion 310 as shown in FIG. 5A. In addition, the spacing between the corner RC of the exposed pad 402 (i.e., the spacing S1C) (FIG. 5B) is greater than the spacing S2C between the leads 206 and the extension portion 310.

In the cross-sectional view along the extending direction of the extension portion 310 (FIG. 5A), the thickness T1C of the exposed pad 402 is the same as the thickness T3C of the extension portion 310. The top surface 402T of the exposed pad 402 is flush with the top surface 310T of the extension portion 310.

As shown in FIG. 5A-5B, the extension portions 310-1, 310-2, 310-3, 310-4 may extend on a plane of the bottom surface 402B of the exposed pad 402. In some embodiments, the bottom surface 402B of the exposed pad 402 is flush with the bottom surfaces 310-1B, 310-2B, 310-3B, and 310-4B of the extension portions 310-1, 310-2, 310-3, and 310-4. In some embodiments, each of the extension portions 310-1, 310-2, 310-3, 310-4 may overlap at least one of the leads 206 along the corresponding side surfaces 402S1, 402S2, 402S3, and 402S4 of the exposed pad 402.

As shown in FIGS. 5A-5B, the die 230 is mounted on the top surface 402T of the exposed pad 402. The molding compound 240 may encapsulate the die 230 and covers the leadframe 200C. In some embodiments, the bottom surface 402B of the exposed pad 402 and the bottom surfaces 310-1B, 310-2B, 310-3B, and 310-4B of the extension portions 310-1, 310-2, 310-3, and 310-4 are exposed from the molding compound 240.

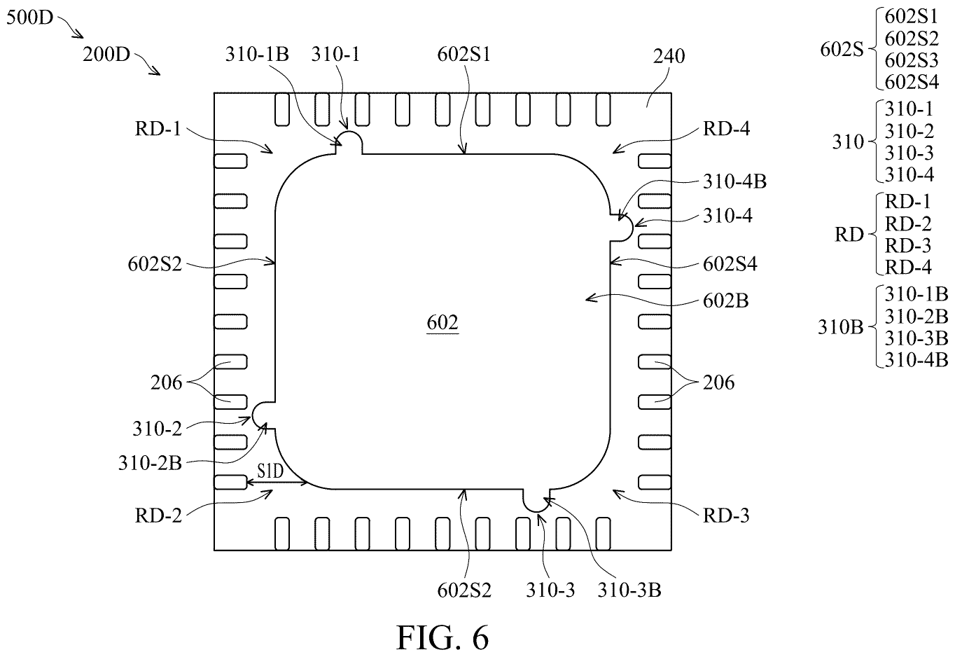

FIG. 6 is a schematic bottom view of a semiconductor package 500D in accordance with some embodiments of the disclosure. Elements of the embodiments that are the same or similar to those previously described with reference to FIG. 1, and 4 are not repeated herein, in the interests of brevity.

As shown in FIGS. 4 and 6, the difference between the semiconductor package 500C and the semiconductor package 500D at least includes that the semiconductor package 500D includes a leadframe 200D having a rounded rectangular exposed pad 602.

As shown in FIG. 6, the exposed pad 602 having a rounded rectangular shape may include four side surface 602S1, 602S2, 602S3, and 602S4 and four corners RD-1, RD-2, RD-3, and RD-4. In some embodiments, the corners RD-1, RD-2, RD-3, and RD-4 are rounded corners.

In some embodiments, the four extension portions 310-1, 310-2, 310-3, 310-4 are connected to the four side surfaces 602S1, 602S2, 602S3, and 602S4 of the exposed pad 602, respectively. For example, the extension portion 310-1 is connected to the side surface 602S1 adjacent to the side surfaces 602S2, 602S4 and close to the corner RD-1 between the side surface 602S1 and 602S2. The extension portion 310-2 is connected to the side surface 602S2 adjacent to the side surfaces 602S1, 602S3 and close to the corner RD-2 between the side surface 602S2 and 602S3. The extension portion 310-3 is connected to the side surface 602S3 adjacent to the side surfaces 602S2, 602S4 and close to the corner RD-3 between the side surface 602S3 and 602S4. The extension portion 310-4 is connected to the side surface 602S4 adjacent to the side surfaces 602S3, 602S1 and close to the corner RD-4 between the side surface 602S4 and 602S1.

Alternatively, the extension portion 310-1 is connected to the side surface 602S1 adjacent to the side surfaces 602S2, 602S4 and close to the corner RD-4 between the side surface 602S1 and 602S4. The extension portion 310-2 is connected to the side surface 602S2 adjacent to the side surfaces 602S1, 602S3 and close to the corner RD-1 between the side surface 602S1 and 602S2. The extension portion 310-3 is connected to the side surface 602S3 adjacent to the side surfaces 602S2, 602S4 and close to the corner RD-2 between the side surface 602S2 and 602S3. The extension portion 310-4 is connected to the side surface 602S4 adjacent to the side surfaces 602S3, 602S1 and close to the corner RD-3 between the side surface 602S3 and 602S4.

In some embodiments, since the extension portions 310-1, 310-2, 310-3, and 310-4 are close to different corners RD-1, RD-2, RD-3, and RD-4 of the exposed pad 602, the extension portion 310-1 is arranged far from the extension portions 310-2 and 310-4, the extension portion 310-2 is arranged far from the extension portions 310-1 and 310-3, the extension portion 310-3 is arranged far from the extension portions 310-2 and 310-4, and the extension portion 310-4 is arranged far from the extension portions 310-3 and 310-1.

In some embodiments, the extension portions 310-1, 310-2, 310-3, and 310-4 are not connected to the central portion of the corresponding side surfaces 602S1, 602S2, 602S3, and 602S4 of the exposed pad 602.

In some embodiments, the extension portions 310-1, 310-2, 310-3, and 310-4 may extend outwardly the corresponding side surfaces 602S1, 602S2, 602S3, and 602S4 of the exposed pad 602. For example, the extension portion 310-1 may extend substantially vertical to the side surface 602S1 of the exposed pad 602. The extension portion 310-2 may extend substantially vertical to the side surface 602S2 of the exposed pad 602. The extension portion 310-3 may extend substantially vertical to the side surface 602S3 of the exposed pad 602. The extension portion 310-4 may extend substantially vertical to the side surface 602S4 of the exposed pad 602. Since the side surface 602S1 is substantially vertical to the side surfaces 602S2 and 602S4, the extension portion 310-1 is substantially vertical to the extension portions 310-2 and 310-4. Since the side surface 602S2 is substantially vertical to the side surfaces 602S1 and 602S3, the extension portion 310-2 is substantially vertical to the extension portions 310-1 and 310-3. Since the side surface 602S3 is substantially vertical to the side surfaces 602S2 and 602S4, the extension portion 310-3 is substantially vertical to the extension portions 310-2 and 310-4. Since the side surface 602S4 is substantially vertical to the side surfaces 602S3 and 602S1, the extension portion 310-4 is substantially vertical to the extension portions 310-3 and 310-1.

In some embodiments, the cross-sectional view along the extending direction of the extension portion 310 of the semiconductor package 500D may be the same or similar to the cross-sectional view along the extending direction of the extension portion 310 of the semiconductor package 500C (FIG. 5A). In addition, the cross-sectional view along the side surface 602S of the exposed pad 602 of the semiconductor package 500D may be the same or similar to the cross-sectional view along the side surface 402S of the exposed pad 402 of the semiconductor package 500C (FIG. 5B) except for the spacing S1D (labeled in FIG. 6) between the lead 206 and the corner RD of the exposed pad 602 of the semiconductor package 500D is greater than the spacing between the lead 206 and the corner RC of the exposed pad 402 (i.e., the spacing S1C) of the semiconductor package 500C.

In some embodiments, the extension portions 310-1, 310-2, 310-3, 310-4 may extend on a plane of the bottom surface 602B of the exposed pad 602. In some embodiments, the bottom surface 602B of the exposed pad 602 is flush with the bottom surfaces 310-1B, 310-2B, 310-3B, and 310-4B of the extension portions 310-1, 310-2, 310-3, and 310-4. In some embodiments, each of the extension portions 310-1, 310-2, 310-3, 310-4 may overlap at least one of the leads 206 along the corresponding side surfaces 602S1, 602S2, 602S3, and 602S4 of the exposed pad 602.

Similar to the semiconductor package 500C, the die 230 is mounted on the top surface of the exposed pad 602 opposite the bottom surface 602B. The molding compound 240 may encapsulate the die 230 and covers the leadframe 200D. In some embodiments, the bottom surface 602B of the exposed pad 602 and the bottom surfaces 310-1B, 310-2B, 310-3B, and 310-4B of the extension portions 310-1, 310-2, 310-3, and 310-4 are exposed from the molding compound 240 (FIG. 6).

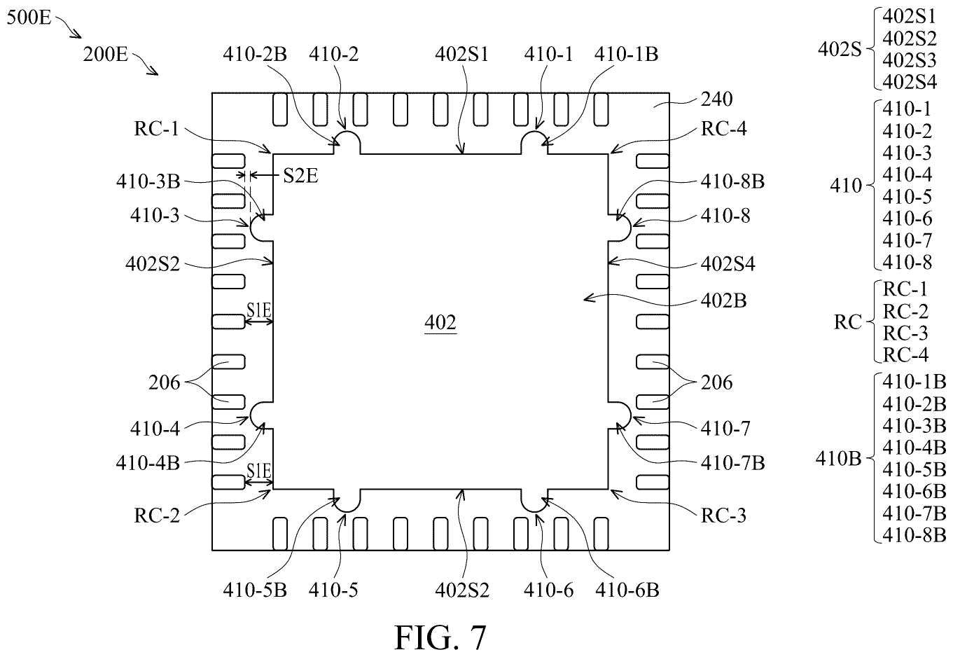

FIG. 7 is a schematic bottom view of a semiconductor package 500E in accordance with some embodiments of the disclosure. Elements of the embodiments that are the same or similar to those previously described with reference to FIGS. 1, 4 and 6 are not repeated herein, in the interests of brevity.

As shown in FIGS. 4 and 7, the difference between the semiconductor package 500C and the semiconductor package 500E at least includes that the semiconductor package 500E includes a leadframe 200E having at least two extension portions 410 connected to the same side surface 402S of the exposed pad 402 and close to different corners of the exposed pad 402.

As shown in FIG. 7, the exposed pad 402 having a rectangular shape may include four side surface 402S1, 402S2, 402S3, and 402S4 and four corners RC-1, RC-2, RC-3, and RC-4. In some embodiments, the corners RC-1, RC-2, RC-3, and RC-4 are sharp corners.

In some embodiments, there are eight extension portions 410-1, 410-2, 410-3, 410-4, 410-5, 410-6, 410-7, and 410-8 connected to the four side surfaces 402S1, 402S2, 402S3, and 402S4 of the exposed pad 402. More specifically, the extension portions 410-1 and 410-2 are connected to the same side surface 402S1 adjacent to the side surfaces 402S2, 402S4. In addition, the extension portions 410-1 and 410-2 are close to the different corners RC-4 and RC-1, respectively. The extension portions 410-3 and 410-4 are connected to the same side surface 402S2 adjacent to the side surfaces 402S1, 402S3. In addition, the extension portions 410-3 and 410-4 are close to the different corners RC-1 and RC-2, respectively. The extension portions 410-5 and 410-6 are connected to the same side surface 402S3 adjacent to the side surfaces 402S2, 402S4. In addition, the extension portions 410-5 and 410-6 are close to the different corners RC-2 and RC-3, respectively. The extension portions 410-7 and 410-8 are connected to the same side surface 402S4 adjacent to the side surfaces 402S1, 402S3. In addition, the extension portions 410-7 and 410-8 are close to the different corners RC-3 and RC-4, respectively.

In some embodiments, the extension portions 410-2 and 410-3 close to the corner RC-1 are close to each other. The extension portions 410-4 and 410-5 close to the corner RC-2 are close to each other. The extension portions 410-6 and 410-7 close to the corner RC-3 are close to each other. The extension portions 410-8 and 410-5 close to the corner RC-4 are close to each other.

In some embodiments, the extension portions 410-1, 410-2, 410-3, 410-4, 410-5, 410-6, 410-7, and 410-8 are not connected to the central portion of the corresponding side surfaces 402S1, 402S2, 402S3, and 402S4 of the exposed pad 402.

In some embodiments, the extension portions 410-1, 410-2, 410-3, 410-4, 410-5, 410-6, 410-7, and 410-8 may extend outwardly the corresponding side surfaces 402S1, 402S2, 402S3, and 402S4 of the exposed pad 402. For example, the extension portions 410-1 and 410-2 may extend substantially vertical to the side surface 402S1 of the exposed pad 402. The extension portions 410-3 and 410-4 may extend substantially vertical to the side surface 402S2 of the exposed pad 402. The extension portions 410-5 and 410-6 may extend substantially vertical to the side surface 402S3 of the exposed pad 402. The extension portions 410-7 and 410-8 may extend substantially vertical to the side surface 402S4 of the exposed pad 402. Since the side surface 402S1 is substantially vertical to the side surfaces 402S2 and 402S4, the extension portions 410-1 and 410-2 are substantially vertical to the extension portions 410-3, 410-4, 410-7, and 410-8. Since the side surface 402S2 is substantially vertical to the side surfaces 402S1 and 402S3, the extension portions 410-3 and 410-4 are substantially vertical to the extension portions 410-1, 410-2, 410-5, and 410-6. Since the side surface 402S3 is substantially vertical to the side surfaces 402S2 and 402S4, the extension portions 410-5, and 410-6 are substantially vertical to the extension portions 410-3, 410-4, 410-7, and 410-8. Since the side surface 402S4 is substantially vertical to the side surfaces 402S3 and 402S1, the extension portions 410-7 and 410-8 are substantially vertical to the extension portions 410-1, 410-2, 410-5, and 410-6.

In some embodiments, the cross-sectional view along the extending direction of the extension portion 410 of the semiconductor package 500E may be the same or similar to the cross-sectional view along the side surface 202S of the exposed pad 202 of the semiconductor package 500A or 500B (FIG. 2B or 3B). In addition, the cross-sectional view along the side surface 402S of the exposed pad 402 of the semiconductor package 500E may be the same or similar to the cross-sectional view along the side surface 402S of the exposed pad 402 of the semiconductor package 500C (FIG. 5B).

In some embodiments in which the extension portions 410 extend outwardly the corresponding side surfaces 402S1, 402S2, 402S3, and 402S4 of the exposed pad 402 (and toward to leads 206) of the semiconductor package 500E, the spacing S1E between the leads 206 and the exposed pad 402 is greater than the spacing S2E between the leads 206 and the extension portion 410. In addition, the spacing between the corner RC of the exposed pad 402 (i.e., the spacing S1E) is greater than the spacing S2E between the leads 206 and the extension portion 410 labeled in FIG. 7.

In some embodiments, the extension portions 410-1, 410-2, 410-3, 410-4, 410-5, 410-6, 410-7, and 410-8 may extend on a plane of the bottom surface 402B of the exposed pad 402. In some embodiments, the bottom surface 402B of the exposed pad 402 is flush with the bottom surfaces 410-1B, 410-2B, 410-3B, 410-4B, 410-5B, 410-6B, 410-7B, and 410-8B of the extension portions 410-1, 410-2, 410-3, 410-4, 410-5, 410-6, 410-7, and 410-8. In some embodiments, each of the extension portions 410-1, 410-2, 410-3, 410-4, 410-5, 410-6, 410-7, and 410-8 may overlap at least one of the leads 206 along the corresponding side surfaces 402S1, 402S2, 402S3, and 402S4 of the exposed pad 402.

Similar to the semiconductor package 500C, the die 230 is mounted on the top surface of the exposed pad 402 opposite the bottom surface 402B. The molding compound 240 may encapsulate the die 230 and covers the leadframe 200E. In some embodiments, the bottom surface 402B of the exposed pad 402 and the bottom surfaces 410-1B, 410-2B, 410-3B, 410-4B, 410-5B, 410-6B, 410-7B, and 410-8B of the extension portions 410-1, 410-2, 410-3, 410-4, 410-5, 410-6, 410-7, and 410-8 are exposed from the molding compound 240. (FIG. 7).

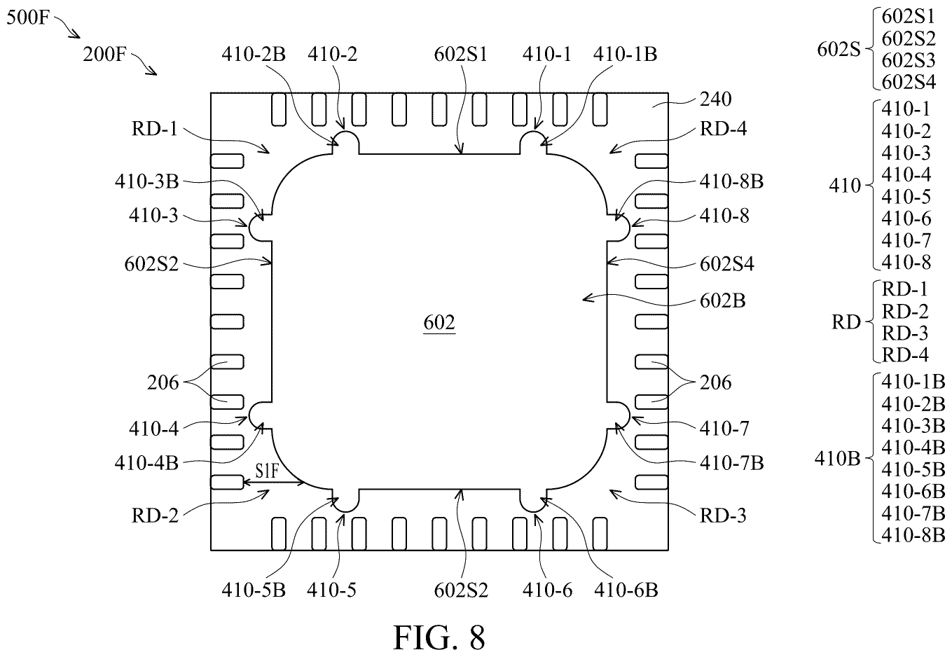

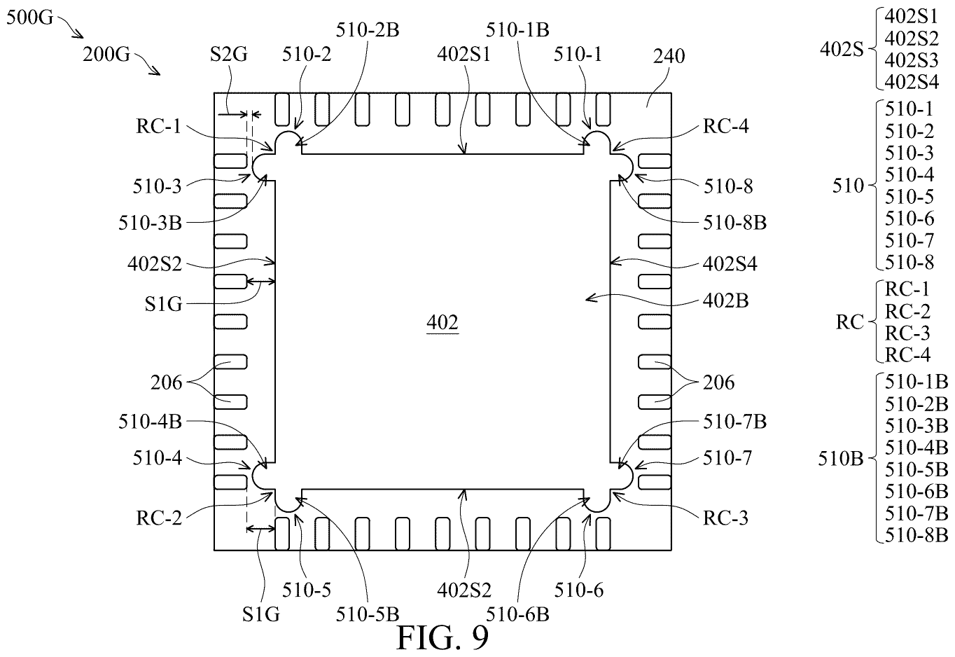

FIG. 8 is a schematic bottom view of a semiconductor package 500F in accordance with some embodiments of the disclosure. Elements of the embodiments that are the same or similar to those previously described with reference to FIGS. 1, 4, 6 and 7 are not repeated herein, in the interests of brevity.

As shown in FIGS. 7 and 8, the difference between the semiconductor package 500E and the semiconductor package 500F at least includes that the semiconductor package 500F includes a leadframe 200F having a rounded rectangular exposed pad 602, whereas the leadframe 200E in the semiconductor package 500E has a rectangular exposed pad 402. The spacing S1F (labeled in FIG. 8) between the lead 206 and the corner RD of the exposed pad 602 of the semiconductor package 500F is greater than the spacing between the lead 206 and the corner RC of the exposed pad 402 (i.e., the spacing S1E) of the semiconductor package 500E.

As shown in FIG. 8, the exposed pad 602 having a rounded rectangular shape may include four side surface 602S1, 602S2, 602S3, and 602S4 and four corners RD-1, RD-2, RD-3, and RD-4. In some embodiments, the corners RD-1, RD-2, RD-3, and RD-4 are rounded corners.

In some embodiments, there are eight extension portions 410-1, 410-2, 410-3, 410-4, 410-5, 410-6, 410-7, and 410-8 connected to the four side surfaces 602S1, 602S2, 602S3, and 602S4 of the exposed pad 602. More specifically, the extension portions 410-1 and 410-2 are connected to the same side surface 602S1 adjacent to the side surfaces 602S2, 602S4. In addition, the extension portions 410-1 and 410-2 are close to the different corners RD-4 and RD-1, respectively. The extension portions 410-3 and 410-4 are connected to the same side surface 602S2 adjacent to the side surfaces 602S1, 602S3. In addition, the extension portions 410-3 and 410-4 are close to the different corners RD-1 and RD-2, respectively. The extension portions 410-5 and 410-6 are connected to the same side surface 602S3 adjacent to the side surfaces 602S2, 602S4. In addition, the extension portions 410-5 and 410-6 are close to the different corners RD-2 and RD-3, respectively. The extension portions 410-7 and 410-8 are connected to the same side surface 602S4 adjacent to the side surfaces 602S1, 602S3. In addition, the extension portions 410-7 and 410-8 are close to the different corners RD-3 and RD-4, respectively.

In some embodiments, the extension portions 410-1, 410-2, 410-3, 410-4, 410-5, 410-6, 410-7, and 410-8 are not connected to the central portion of the corresponding side surfaces 602S1, 602S2, 602S3, and 602S4 of the exposed pad 602.

In some embodiments, the extension portions 410-1, 410-2, 410-3, 410-4, 410-5, 410-6, 410-7, and 410-8 may extend outwardly the corresponding side surfaces 602S1, 602S2, 602S3, and 602S4 of the exposed pad 602. For example, the extension portions 410-1 and 410-2 may extend substantially vertical to the side surface 602S1 of the exposed pad 602. The extension portions 410-3 and 410-4 may extend substantially vertical to the side surface 602S2 of the exposed pad 602. The extension portions 410-5 and 410-6 may extend substantially vertical to the side surface 602S3 of the exposed pad 602. The extension portions 410-7 and 410-8 may extend substantially vertical to the side surface 602S4 of the exposed pad 602. Since the side surface 602S1 is substantially vertical to the side surfaces 602S2 and 602S4, the extension portions 410-1 and 410-2 are substantially vertical to the extension portions 410-3, 410-4, 410-7, and 410-8. Since the side surface 602S2 is substantially vertical to the side surfaces 602S1 and 602S3, the extension portions 410-3 and 410-4 are substantially vertical to the extension portions 410-1, 410-2, 410-5, and 410-6. Since the side surface 602S3 is substantially vertical to the side surfaces 602S2 and 602S4, the extension portions 410-5, and 410-6 are substantially vertical to the extension portions 410-3, 410-4, 410-7, and 410-8. Since the side surface 602S4 is substantially vertical to the side surfaces 602S3 and 602S1, the extension portions 410-7 and 410-8 are substantially vertical to the extension portions 410-1, 410-2, 410-5, and 410-6.

In some embodiments, the cross-sectional view along the extending direction of the extension portion 410 of the semiconductor package 500F may be the same or similar to the cross-sectional view along the side surface 202S of the exposed pad 202 of the semiconductor package 500A or 500B (FIG. 2B or 3B). In addition, the cross-sectional view along the side surface 402S of the exposed pad 402 of the semiconductor package 500F may be the same or similar to the cross-sectional view along the side surface 402S of the exposed pad 402 of the semiconductor package 500C (FIG. 5B) except for the spacing S1F (labeled in FIG. 8) between the corner RD of the exposed pad 602 is greater than the corner RC of the exposed pad 402 (i.e., the spacing S1C).

In some embodiments, the extension portions 410-1, 410-2, 410-3, 410-4, 410-5, 410-6, 410-7, and 410-8 may extend on a plane of the bottom surface 602B of the exposed pad 602. In some embodiments, the bottom surface 602B of the exposed pad 602 is flush with the bottom surfaces 410-1B, 410-2B, 410-3B, 410-4B, 410-5B, 410-6B, 410-7B, and 410-8B of the extension portions 410-1, 410-2, 410-3, 410-4, 410-5, 410-6, 410-7, and 410-8. In some embodiments, each of the extension portions 410-1, 410-2, 410-3, 410-4, 410-5, 410-6, 410-7, and 410-8 may overlap at least one of the leads 206 along the corresponding side surfaces 602S1, 602S2, 602S3, and 602S4 of the exposed pad 602.

Similar to the semiconductor package 500A or 500B, the die 230 is mounted on the top surface of the exposed pad 602 opposite the bottom surface 602B. The molding compound 240 may encapsulate the die 230 and covers the leadframe 200F. In some embodiments, the bottom surface 602B of the exposed pad 602 and the bottom surfaces 410-1B, 410-2B, 410-3B, 410-4B, 410-5B, 410-6B, 410-7B, and 410-8B of the extension portions 410-1, 410-2, 410-3, 410-4, 410-5, 410-6, 410-7, and 410-8 are exposed from the molding compound 240. (FIG. 8).

FIG. 9 is a schematic bottom view of a semiconductor package 500G in accordance with some embodiments of the disclosure. Elements of the embodiments that are the same or similar to those previously described with reference to FIGS. 1, 4 and 6-8 are not repeated herein, in the interests of brevity.

As shown in FIGS. 7 and 9, the difference between the semiconductor package 500E and the semiconductor package 500G at least includes that the semiconductor package 500G includes a leadframe 200G having at least two extension portions 510 connected to the same side surface 402S. The at least two extension portions 510 are closer to (e.g., adjacent to) different corners of the exposed pad 402 than the extension portions 410 of the semiconductor package 500E.

As shown in FIG. 9, the exposed pad 402 having a rectangular shape may include four side surface 402S1, 402S2, 402S3, and 402S4 and four corners RC-1, RC-2, RC-3, and RC-4.

In some embodiments, there are eight extension portions 510-1, 510-2, 510-3, 510-4, 510-5, 510-6, 510-7, and 510-8 connected to the four side surfaces 402S1, 402S2, 402S3, and 402S4 of the exposed pad 402. More specifically, the extension portions 510-1 and 510-2 are connected to the same side surface 402S1 adjacent to the side surfaces 402S2, 402S4. In addition, the extension portions 510-1 and 510-2 are adjacent to the different corners RC-4 and RC-1, respectively. The extension portions 510-3 and 510-4 are connected to the same side surface 402S2 adjacent to the side surfaces 402S1, 402S3. In addition, the extension portions 510-3 and 510-4 are adjacent to the different corners RC-1 and RC-2, respectively. The extension portions 510-5 and 510-6 are connected to the same side surface 402S3 adjacent to the side surfaces 402S2, 402S4. In addition, the extension portions 510-5 and 510-6 are adjacent to the different corners RC-2 and RC-3, respectively. The extension portions 510-7 and 510-8 are connected to the same side surface 402S4 adjacent to the side surfaces 402S1, 402S3. In addition, the extension portions 510-7 and 510-8 are adjacent to the different corners RC-3 and RC-4, respectively.

In some embodiments, the extension portion 510-2 and 510-3 adjacent to the corner RC-1 are adjacent to each other. The extension portion 510-4 and 510-5 adjacent to the corner RC-2 are adjacent to each other. The extension portion 510-6 and 510-7 adjacent to the corner RC-3 are adjacent to each other. The extension portion 510-8 and 510-5 adjacent to the corner RC-4 are adjacent to each other.

In some embodiments, the extension portions 510-1, 510-2, 510-3, 510-4, 510-5, 510-6, 510-7, and 510-8 are not connected to the central portion of the corresponding side surfaces 402S1, 402S2, 402S3, and 402S4 of the exposed pad 402.

In some embodiments, the extension portions 510-1, 510-2, 510-3, 510-4, 510-5, 510-6, 510-7, and 510-8 may extend outwardly the corresponding side surfaces 402S1, 402S2, 402S3, and 402S4 of the exposed pad 402. For example, the extension portions 510-1 and 510-2 may extend substantially vertical to the side surface 402S1 of the exposed pad 402. The extension portions 510-3 and 510-4 may extend substantially vertical to the side surface 402S2 of the exposed pad 402. The extension portions 510-5 and 510-6 may extend substantially vertical to the side surface 402S3 of the exposed pad 402. The extension portions 510-7 and 510-8 may extend substantially vertical to the side surface 402S4 of the exposed pad 402. Since the side surface 402S1 is substantially vertical to the side surfaces 402S2 and 402S4, the extension portions 510-1 and 510-2 are substantially vertical to the extension portions 510-3, 510-4, 510-7, and 510-8. Since the side surface 402S2 is substantially vertical to the side surfaces 402S1 and 402S3, the extension portions 510-3 and 510-4 are substantially vertical to the extension portions 510-1, 510-2, 510-5, and 510-6. Since the side surface 402S3 is substantially vertical to the side surfaces 402S2 and 402S4, the extension portions 510-5, and 510-6 are substantially vertical to the extension portions 510-3, 510-4, 510-7, and 510-8. Since the side surface 402S4 is substantially vertical to the side surfaces 402S3 and 402S1, the extension portions 510-7 and 510-8 are substantially vertical to the extension portions 510-1, 510-2, 510-5, and 510-6.

In some embodiments, the cross-sectional view along the extending direction of the extension portion 510 of the semiconductor package 500G and the cross-sectional view along the side surface 402S of the exposed pad 402 of the semiconductor package 500E may be the same or similar to the cross-sectional view along the side surface 202S of the exposed pad 202 of the semiconductor package 500A or 500B (FIG. 2B or 3B).

In some embodiments in which the extension portions 510 extend outwardly the corresponding side surfaces 402S1, 402S2, 402S3, and 402S4 of the exposed pad 402 (and toward to leads 206) of the semiconductor package 500G, the spacing S1G between the leads 206 and the exposed pad 402 is greater than the spacing S2G between the leads 206 and the extension portion 510. In addition, the spacing between the corner RC of the exposed pad 402 (i.e., the spacing S1G) is greater than the spacing S2G between the leads 206 and the extension portion 510 labeled in FIG. 9.

In some embodiments, the extension portions 510-1, 510-2, 510-3, 510-4, 510-5, 510-6, 510-7, and 510-8 may extend on a plane of the bottom surface 402B of the exposed pad 402. In some embodiments, the bottom surface 402B of the exposed pad 402 is flush with the bottom surfaces 510-1B, 510-2B, 510-3B, 510-4B, 510-5B, 510-6B, 510-7B, and 510-8B of the extension portions 510-1, 510-2, 510-3, 510-4, 510-5, 510-6, 510-7, and 510-8. In some embodiments, each of the extension portions 510-1, 510-2, 510-3, 510-4, 510-5, 510-6, 510-7, and 510-8 may overlap at least one of the leads 206 along the corresponding side surfaces 402S1, 402S2, 402S3, and 402S4 of the exposed pad 402.

Similar to the semiconductor package 500A or 500B, the die 230 is mounted on the top surface of the exposed pad 402 opposite the bottom surface 402B. The molding compound 240 may encapsulate the die 230 and covers the leadframe 200G. In some embodiments, the bottom surface 402B of the exposed pad 402 and the bottom surfaces 510-1B, 510-2B, 510-3B, 510-4B, 510-5B, 510-6B, 510-7B, and 510-8B of the extension portions 510-1, 510-2, 510-3, 510-4, 510-5, 510-6, 510-7, and 510-8 are exposed from the molding compound 240. (FIG. 9).

The semiconductor package (e.g., the semiconductor packages 500A, 500B, 500C, 500D, 500E, 500F, 500G) includes a leadframe (e.g., the leadframes 200A, 200B, 200C, 200D, 200E, 200F, 200G) having an exposed pad (e.g., the exposed pads 202, 302, 402, 602), a die (e.g., the die 230), and a molding compound (e.g., the molding compound 240). The leadframe further includes at least one extension portion (e.g., the extension portions 210, 210-1, 210-2, 210-3, 210-4, 310, 310-1, 310-2, 310-3, 310-4, 410, 410-1, 410-2, 410-3, 410-4, 410-5, 410-6, 410-7, 410-8, 510, 510-1, 510-2, 510-3, 510-4, 510-5, 510-6, 510-7, 510-8) arranged on corners (e.g., the corners RA, RA-1, RA-2, RA-3, RA-4) or side surface portions (e.g., the surface portions 402S, 402S1, 402S2, 402S3, 402S4, 602S, 602S1, 602S2, 602S3, 602S4) close to the corresponding corners (e.g., the corners RC, RC-1, RC-2, RC-3, RC-4, RD, RD-1, RD-2, RD-3, RD-4) of the exposed pad (e.g., the exposed pads 402, 602). The extension portion laterally protrude from corners or adjacent side surfaces of the exposed pad may serve as an extra wing portion (or a protruding portion) of the exposed pad. In addition, the bottom surface (e.g., the bottom surfaces 210-1B, 210-2B, 210-3B, 210-4B, 310-1B, 310-2B, 310-3B, 310-4B, 410-1B, 410-2B, 410-3B, 410-4B, 410-5B, 410-6B, 410-7B, 410-8B, 510-1B, 510-2B, 510-3B, 510-4B, 510-5B, 510-6B, 510-7B, 510-8B) of the at least one extension portion and the bottom surface (e.g., the bottom surfaces 202B, 302B, 402B, 602B) of the exposed pad (e.g., the exposed pads 202, 302, 402, 602) are coplanar and exposed from the molding compound. When the semiconductor package is bent by an external force during processes including handling, electrical testing, shipping and surface mount technology (SMT) printed circuit board (PCB) assembly. The extension portion connected to the exposed pad can changes the stress field, making it harder to bend and reducing stress at the side surfaces of the exposed pad. The extension portion can also act as an effective crack stopper, which can prevent cracks from easily propagating along the interface between the exposed pad and the molding compound and at the side surfaces of the exposed pad. The extension portion can also prevent cracks propagating to the adjacent semiconductor packages in the same leadframe strip matrix.

Embodiments of the disclosure provide a semiconductor package (e.g., a QFN type package). The semiconductor package includes an exposed pad, at least one extension portion, a die, and a molding compound. The at least one extension portion is connected to the exposed pad and extends on a plane of a bottom surface of the exposed pad. The die is mounted on a top surface of the exposed pad. The top surface is opposite the bottom surface. The molding compound encapsulates the die and surrounds the exposed pad and the at least one extension portion. The bottom surface of the exposed pad and a bottom surface of the at least one extension portion are exposed from the molding compound.

In some embodiments, the at least one extension portion is connected to a corner of the exposed pad.

In some embodiments the at least one extension portion extends outwardly substantially along a diagonal of the exposed pad.

In some embodiments, the semiconductor package further includes a tie bar extending from the corner of the exposed pad. The at least one extension portion overlaps the tie bar.

In some embodiments, wherein a thickness of the exposed pad is the same as a thickness of the extension portion.

In some embodiments, a top surface of the exposed pad is flush with a top surface of the extension portion.

In some embodiments, a thickness of the exposed pad is a sum of a thickness of the extension portion and a thickness of the tie bar.

In some embodiments, the at least one extension portion is connected to a first side surface of the exposed pad.

In some embodiments, the semiconductor package further includes leads arranged along the first side surface of the exposed pad and spaced apart from the exposed pad. The at least one extension portion is located between the exposed pad and the leads.

In some embodiments, the semiconductor package further includes an additional extension portion connected to a second side surface of the exposed pad, wherein the second side surface is adjacent to the first side surface.

In some embodiments, the at least one extension portion and the additional extension portion are located close to a corner of the exposed pad between the first side surface and the second side surface.

In some embodiments, the first extension portion and the second extension portion are located close to different corners of the exposed pad.

In some embodiments, a corner of the exposed pad between the first side surface and the second side surface is a sharp corner or a rounded corner.

In some embodiments, the bottom surface of the exposed pad is flush with the bottom surface of the at least one extension portion.

In some embodiments, the at least one extension portion has a smooth outer contour.

In some embodiments, in a plane view, the exposed pad is a rectangular or rounded rectangular or circular shape.

Embodiments of the disclosure provide a semiconductor package (e.g., a QFN type package). The semiconductor package includes a leadframe, a die, and a molding compound. The leadframe includes an exposed pad, a tie bar, leads and a first extension portion. The tie bar extends from a corner of the exposed pad. The leads are arranged around and spaced apart from the exposed pad. The first extension portion is connected to the exposed pad. The first extension portion overlaps at least one of the leads or the tie bar. The die is mounted on a top surface of the exposed pad. The molding compound encapsulates the die and covering the leadframe. A bottom surface of the exposed pad and a bottom surface of the first extension portion are exposed from the molding compound.

In some embodiments, the first extension portion is connected to a corner of the exposed pad.

In some embodiments, the semiconductor package further includes a second extension portion connected to the exposed pad. A bottom surface of the second extension portion is exposed from the molding compound.

In some embodiments, the first extension portion and the second extension portion are close to the same corner of the exposed pad.

In some embodiments, the first extension portion and the second extension portion are close to different corners of the exposed pad.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor package, comprising:
an exposed pad;
at least one extension portion connected to the exposed pad and extending on a plane of a bottom surface of the exposed pad;
a die mounted on a top surface of the exposed pad, wherein the top surface is opposite the bottom surface; and
a molding compound encapsulating the die and surrounding the exposed pad and the at least one extension portion,
wherein the bottom surface of the exposed pad and a bottom surface of the at least one extension portion are exposed from the molding compound.

2. The semiconductor package as claimed in claim 1, wherein the at least one extension portion is connected to a corner of the exposed pad.

3. The semiconductor package as claimed in claim 1, wherein the at least one extension portion extends outwardly substantially along a diagonal of the exposed pad.

4. The semiconductor package as claimed in claim 2, further comprising:
a tie bar extending from the corner of the exposed pad,
wherein the at least one extension portion overlaps the tie bar.

5. The semiconductor package as claimed in claim 1, wherein a thickness of the exposed pad is the same as a thickness of the extension portion.

6. The semiconductor package as claimed in claim 1, wherein a top surface of the exposed pad is flush with a top surface of the extension portion.

7. The semiconductor package as claimed in claim 4, wherein a thickness of the exposed pad is a sum of a thickness of the extension portion and a thickness of the tie bar.

8. The semiconductor package as claimed in claim 1, wherein the at least one extension portion is connected to a first side surface of the exposed pad.

9. The semiconductor package as claimed in claim 8, further comprising:
leads arranged along the first side surface of the exposed pad and spaced apart from the exposed pad, wherein the at least one extension portion is located between the exposed pad and the leads.

10. The semiconductor package as claimed in claim 1, further comprising:
an additional extension portion connected to a second side surface of the exposed pad, wherein the second side surface is adjacent to the first side surface.

11. The semiconductor package as claimed in claim 10, wherein the at least one extension portion and the additional extension portion are located close to a corner of the exposed pad between the first side surface and the second side surface.

12. The semiconductor package as claimed in claim 10, wherein the first extension portion and the second extension portion are located close to different corners of the exposed pad.

13. The semiconductor package as claimed in claim 10, wherein a corner of the exposed pad between the first side surface and the second side surface is a sharp corner or a rounded corner.

14. The semiconductor package as claimed in claim 1, wherein the bottom surface of the exposed pad is flush with the bottom surface of the at least one extension portion.

15. The semiconductor package as claimed in claim 1, wherein the at least one extension portion has a smooth outer contour.

16. A semiconductor package, comprising:
a leadframe, comprising:
an exposed pad;
a tie bar extending from a corner of the exposed pad;
leads arranged around and spaced apart from the exposed pad; and
a first extension portion connected to the exposed pad, wherein the first extension portion overlaps at least one of the leads;
a die mounted on a top surface of the exposed pad; and
a molding compound encapsulating the die and covering the leadframe,
wherein a bottom surface of the exposed pad and a bottom surface of the first extension portion are exposed from the molding compound.

17. The semiconductor package as claimed in claim 16, wherein the first extension portion is connected to a corner of the exposed pad.

18. The semiconductor package as claimed in claim 16, further comprising:
a second extension portion connected to the exposed pad, wherein a bottom surface of the second extension portion is exposed from the molding compound.

19. The semiconductor package as claimed in claim 18, wherein the first extension portion and the second extension portion are close to the same corner of the exposed pad.

20. The semiconductor package as claimed in claim 18, wherein the first extension portion and the second extension portion are close to different corners of the exposed pad.
